(19) United States
(12) Patent Application Publication
(10) Pub. No.: US 2015/0319847 A1
(43) Pub. Date: Nov. 5, 2015

(54) WIRING SUBSTRATE

(71) Applicant: SAMSUNG ELECTRO-MECHANICS CO., LTD., Suwon-si (KR)

(72) Inventors: Seong Yeon KIM, Suwon-si (KR); Hong In KIM, Suwon-si (KR)

(73) Assignee: SAMSUNG ELECTRO-MECHANICS CO., LTD., Suwon-si (KR)

(21) Appl. No.: 14/689,478

(22) Filed: Apr. 17, 2015

(30) Foreign Application Priority Data
Apr. 30, 2014 (KR) 10-2014-0052816
Nov. 3, 2014 (KR) 10-2014-0151016

(51) Int. Cl. H05K 1/02; H05K 1/11

(52) U.S. Cl. CPC H05K 1/0216; H05K 1/115

(57) ABSTRACT

A wiring substrate may include an insulating layer; a differential signal transmission line including a first wiring formed on a first surface of the insulating layer and a second wiring formed on a second surface of the insulating layer, the first wiring and the second wiring transmitting differential signals; and a ground part including a first ground layer and a second ground layer disposed to be spaced apart from the first wiring by the predetermined distance on the first surface of the insulating layer and a third ground layer and a fourth ground layer disposed to be spaced apart from the second wiring by the predetermined distance on the second surface of the insulating layer.

### CROSS-REFERENCE TO RELATED APPLICATIONS

This application claims the priorities to, and the benefits of, Korean Patent Application Nos. 10-2014-0052816 filed on Apr. 30, 2014 and 10-2014-0151016 filed on Nov. 3, 2014, with the Korean Intellectual Property Office, the disclosures of which are incorporated herein by reference.

### BACKGROUND

The present disclosure relates to a wiring substrate.

In general, a plurality of components may be mounted on a printed circuit board, and wirings for transmitting signals between the components are formed on the printed circuit board. Recently, in accordance with the rapid development of technology in the related art, data signals have been transmitted through the wirings at high speed and the mounted components have also been developed to respond at high speeds.

An electric field induced in a direction of current flow is formed around each wiring by which data is transmitted, and since emissions of such an electric field carry noise in the signal transmitted to adjacent wiring, an electromagnetic interference (EMI) phenomenon which interrupts normal operations of the components may occur.

According to the related art, emissions of such electric fields have been significantly reduced through the use of a pair of wirings transmitting differential signals having the same amplitude as each other and phases opposite to each other in order to solve the above-mentioned problem. Specifically, according to the related art, the emissions of the electric field have been significantly reduced by disposing differential signal lines in parallel to each other, so that magnetic fields generated by respective wirings in different directions are offset by each other.

However, in the case of the printed circuit board using the differential signal transmission lines according to the related art described above, since the pair of wirings may be disposed to be spaced apart from each other by a predetermined distance in a horizontal direction and may be disposed to be spaced apart from neighboring differential signal transmission lines by a predetermined distance or more, while grounds are disposed between the differential signal transmission lines in order to significantly reduce signal distortion due to interference between the differential signal transmission lines, a significant area may be required to form the wirings transmitting the differential signals. Thus, it may be difficult to miniaturize the printed circuit board.

### SUMMARY

An exemplary embodiment in the present disclosure may provide a wiring substrate capable of decreasing an distance between wirings transmitting differential signals by disposing first and second wirings transmitting the differential signals to face each other on the basis of an insulating layer and easily adjusting impedance of differential signal transmission lines by disposing ground layers to be spaced apart from the wirings by a predetermined distance.

According to an exemplary embodiment in the present disclosure, a wiring substrate may include: an insulating layer; a differential signal transmission line including a first wiring provided on a first surface of the insulating layer and a second wiring provided on a second surface of the insulating layer, the first wiring and the second wiring transmitting differential signals; and a ground part including a first ground layer and a second ground layer disposed to be spaced apart from the first wiring by the predetermined distance on the first surface of the insulating layer, and a third ground layer and a fourth ground layer disposed to be spaced apart from the second wiring by the predetermined distance on the second surface of the insulating layer.

According to an exemplary embodiment in the present disclosure, a wiring substrate may include: an insulating layer; a differential signal transmission line including a first wiring provided on an upper surface of the insulating layer and a second wiring provided on a lower surface of the insulating layer, wherein the first wiring and the second wiring transmit differential signals and are disposed to be vertically symmetrical to each other on the basis of the insulating layer; and a ground part including a first ground layer and a second ground layer disposed to be spaced apart from the first wiring by the predetermined distance on the first surface of the insulating layer and a third ground layer and a fourth ground layer disposed to be spaced apart from the second wiring by the predetermined distance on the second surface of the insulating layer, wherein the first ground layer and the third ground layer are disposed to be vertically symmetrical to each other on the basis of the insulating layer, and the second ground layer and the fourth ground layer are disposed to be vertically symmetrical to each other on the basis of the insulating layer.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a view illustrating a wiring substrate according to an exemplary embodiment in the present disclosure;

FIG. 2 is a view illustrating a wiring substrate according to another exemplary embodiment in the present disclosure; FIG. 3 is a view illustrating a wiring substrate according to another exemplary embodiment in the present disclosure;

FIG. 4 is a view illustrating a width of a differential signal transmission line, a thickness of an insulating layer, and a distance between the differential signal transmission line and a ground part for impedance matching; and

FIG. 5 is a view illustrating a shape of an electric field generated by the wiring substrate according to an exemplary embodiment in the present disclosure.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements maybe exaggerated for clarity, and the same reference numerals will be used throughout to designate the same or like elements.

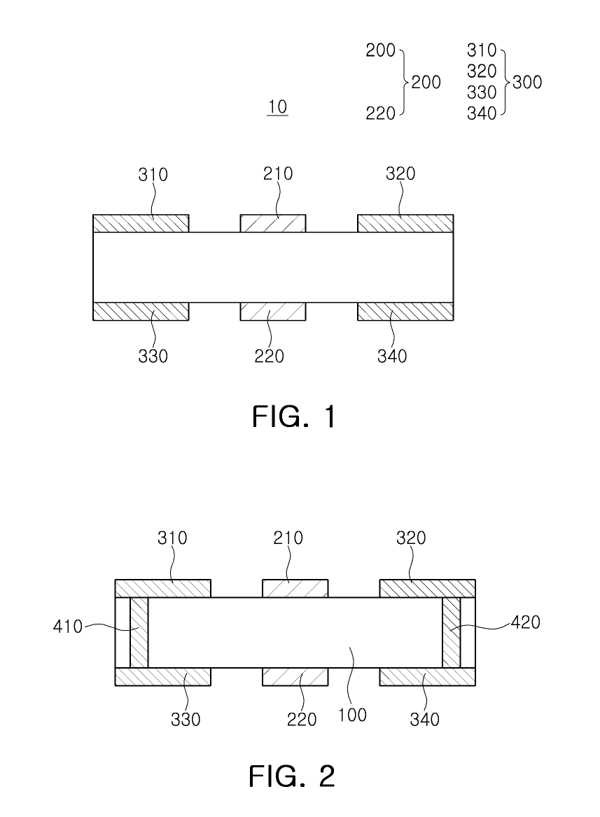

FIG. 1 is a view illustrating a wiring substrate according to an exemplary embodiment in the present disclosure and FIG. 2 is a view illustrating a wiring substrate according to another exemplary embodiment in the present disclosure.

Referring to FIGS. 1 and 2, a wiring substrate 10 according to an exemplary embodiment in the present disclosure may include an insulating layer 100, a differential signal transmission line 200, and a ground part 300. According to an exemplary embodiment, the wiring substrate 10 may further include a first via 410 and a second via 420.

The insulating layer 100 may have a first wiring 210, and a first ground layer 310 and a second ground layer 320 formed on a first surface (upper surface) thereof, wherein the first ground layer 310 and the second ground layer 320 may be disposed to be spaced apart from the first wiring 210 by a predetermined distance on the first surface of the insulating layer 100. In addition, the insulating layer 100 may have a second wiring 220, and a third ground layer 330 and a fourth ground layer 340 formed on a second surface (lower surface) thereof, wherein the third ground layer 330 and the fourth ground layer 340 may be disposed to be spaced apart from the second wiring 220 by the predetermined distance on the second surface of the insulating layer 100.

A thickness d of the insulating layer 100 may be arbitrarily changed in accordance with a capacitance design of the differential signal transmission line 200 and include ceramic powders having a high dielectric constant, for example, barium titanate (BaTiO₃) based powders or strontium titanate (SrTiO₃) based powders. However, the present disclosure is not limited thereto. Various ceramic additives, organic solvents, plasticizers, binders, dispersing agents, and the like may be added to the ceramic powders in accordance with the object of the present disclosure.

An average particle diameter of a ceramic powder used for forming the insulating layer 100 is not particularly limited, but may be adjusted in order to achieve the object of the present disclosure, for example, may be adjusted to 400 nm or less.

The differential signal transmission line 200 may include the first wiring 210 disposed a first surface of the insulating layer 100 and the second wiring 220 disposed on a second surface of the insulating layer 100, and may transmit differential signals.

Here, the differential signals refer to signals having the same amplitude as each other and phases opposite to each other, and the differential signal transmission line 200 transmits a positive polarity signal through the first wiring 210 and transmits a negative polarity signal through the second wiring 220 at the same time, such that electric fields generated by the respective wirings may be offset by an interaction.

Specifically, when the positive polarity signal is converted from a low level to a high level, the negative polarity signal may be converted from the high level to the low level. In this case, directions of currents flowing in both wirings are opposite to each other and the electric fields are formed in directions opposite to the direction of the currents according to Fleming's rule, such that the electric fields may be offset.

The first wiring 210 and the second wiring 220 are disposed on a first surface of the insulating layer 100 and a second surface opposing the first surface, respectively, such that the differential signals transmitted through the first wiring 210 and the second wiring 220 maybe coupled to each other.

As such, since the first wiring 210 and the second wiring 220 have an intersection area which is proportional to a line width, in a case in which the first wiring 210 and the second wiring 220 are disposed to be in parallel to each other in a horizontal direction, the intersection area is larger than that in a case in which the intersection area is proportional to thicknesses of the first and second wirings 210 and 220, and the insulating layer 100 having a higher dielectric constant than air is formed between the first and second wirings 210 and 220, such that capacitances of the wirings may be increased.

In addition, a distance between the wirings may be decreased as compared with a case in which the first wiring and the second wiring are horizontally disposed to be in parallel to each other as in the related art.

Here, widths w of the first wiring 210 and the second wiring 220 and a distance d between the first wiring 210 and the second wiring 220 may be changed depending on target impedance of the differential signal transmission line 200.

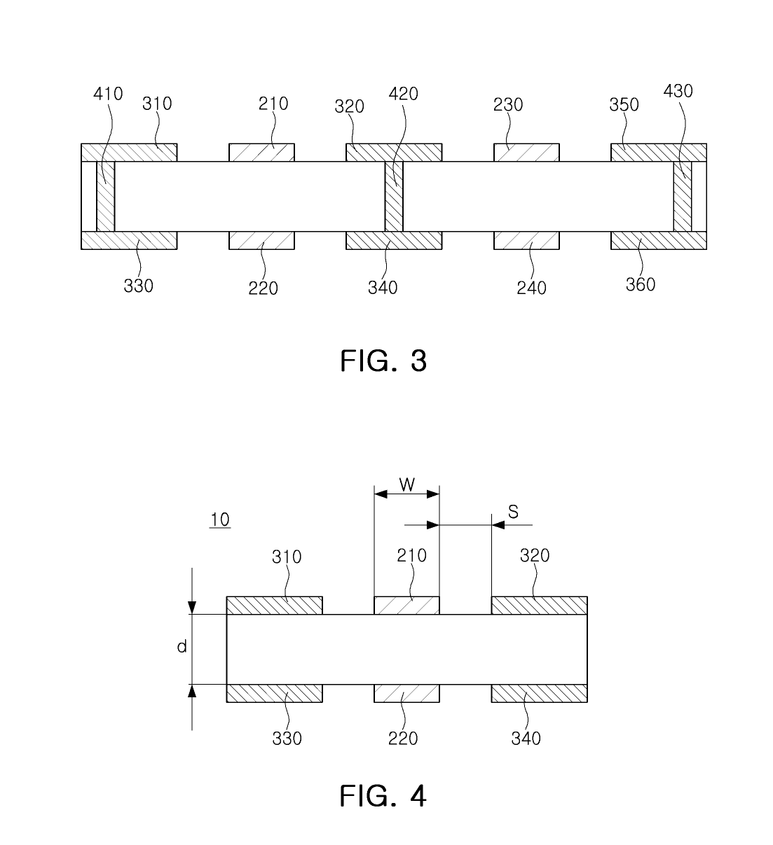

That is, the wiring substrate 10 according to an exemplary embodiment of the present disclosure may perform an impedance matching by adjusting the widths w of the first wiring 210 and the second wiring 220 and the distance between the first wiring 210 and the second wiring 220 (i.e., the thickness of the insulating layer: d). Such impedance matching will be described below in more detail with reference to FIG. 4.

According to an exemplary embodiment of the present disclosure, the differential signal transmission line 200 may be disposed to be vertically symmetrical to each other on the basis of the insulating layer 100.

The ground part 300 may include the first ground layer 310 and the second ground layer 320 formed on a first surface of the insulating layer 100 and disposed to be spaced apart from both sides of the first wiring 210, and the third wiring 330 and the fourth wiring 340 formed on a second surface of the insulating layer 100 and disposed to be spaced apart from both sides of the second wiring 220.

According to an exemplary embodiment, the first ground layer 310 and the third ground layer 330 may be disposed to be vertically symmetrical to each other on the basis of the insulating layer 100 and the second ground layer 320 and the fourth ground layer 340 may be disposed to be vertically symmetrical to each other on the basis of the insulating layer 100.

Here, the first ground layer 310 and the third ground layer 330 may be connected by the first via 410, to have the same reference level. Similarly, the second ground layer 320 and the fourth ground layer 340 may be connected by the second via 420, to have the same reference level.

The first via 410 may connect the first ground layer 310 and the third ground layer 330 to allow the first ground layer 310 and the third ground layer 330 to have the same reference level. In addition, the second via 420 may connect the second ground layer 320 and the fourth ground layer 340 to allow the second ground layer 320 and the fourth ground layer 340 to have the same reference level.

Here, the first via 410 and the second via 420 may be disposed on both sides of an electromagnetic field formed between the first wiring 210 and the second wiring 220 to block radio frequency noise components generated by the wiring transmitting other signals or from the outside, thereby securing isolation with an external signal.

The first via 410 and the second via 420 may be formed by a process of forming via holes and a via fill process at the time of manufacturing the wiring substrate 10, and a method for forming the first via 410 and the second via 420 according to the present disclosure is not particularly limited.

FIG. 3 is a view illustrating a wiring substrate according to another exemplary embodiment in the present disclosure.

Referring to FIG. 3, a wiring substrate 10 according to another exemplary embodiment of the present disclosure may include an insulating layer 100, a plurality of differential signal transmission lines 210, 220, 230, and 240, ground parts 310, 320, 330, and 360, and a plurality of vias 410, 420, and 430.

The wiring substrate according to the present exemplary embodiment is the wiring substrate formed by expanding the wiring substrate according to an exemplary embodiment of FIG. 2 in a horizontal direction in order to dispose the plurality of differential signal transmission lines 210, 220, 230, and 240. Although a pair of differential signal transmission lines 210 and 220, and 230 and 240 is described in the present exemplary embodiment, the present disclosure is not necessarily limited thereto and it is apparent to those skilled in the art that various modifications and alterations may be made without departing from the scope and spirit of the present disclosure.

In the differential signal transmission line, a first wiring 210 and a second wiring 220 may transmit a first differential signal and a third wiring 230 and a fourth wiring 240 may transmit a second differential signal.

The first wiring 210 and the third wiring 230 may be disposed on a first surface of the insulating layer 100 and the second wiring 220 and the fourth wiring 240 may be disposed on a second surface of the insulating layer 100.

Here, the first wiring 210 and the second wiring 220 may be disposed to be vertically symmetrical to each other on the basis of the insulating layer 100 and the third wiring 230 and the fourth wiring 240 may be disposed to be vertically symmetrical to each other on the basis of the insulating layer 100.

A first ground layer 310 may be formed on a first surface of the insulating layer 100 and may be disposed at one side of the first wiring 210 to be spaced apart from the first wiring 210 by a predetermined distance.

A second ground layer 320 may be formed on a first surface of the insulating layer 100, may be disposed between the first wiring 210 and the third wiring 230, and may be disposed to be spaced apart from the first wiring 210 and the third wiring 230 by the predetermined distance.

A fifth ground layer 350 may be formed on a first surface of the insulating layer 100 and may be disposed to be horizontally symmetrical to the second ground layer 320 on the basis of the third wiring 230.

That is, the fifth ground layer 350 may be disposed at an opposing side of the second ground layer 320 on the basis of the third wiring 230 and may be disposed to be spaced apart from the third wiring 230 by the predetermined distance.

The third ground layer 330 may be disposed to be vertically symmetrical to the first ground layer 310 on the basis of the insulating layer 100, the fourth ground layer 340 may be disposed to be vertically symmetrical to the second ground layer 320 on the basis of the insulating layer 100, and a sixth ground layer 360 may be disposed to be vertically symmetrical to the fifth ground layer 350 on the basis of the insulating layer 100.

A first via 410 may connect the first ground layer 310 and the third ground layer 330, a second via 420 may connect the second ground layer 320 and the fourth ground layer 340, and a third via 430 may connect the fifth ground layer 350 and the sixth ground layer 360.

Here, the second via 420 may be disposed between the first wiring 210 and the second wiring 220 transmitting the first differential signal and the third wiring 230 and the fourth wiring 240 transmitting the second differential signal, to block interference between the first differential signal and the second differential signal.

FIG. 4 is a view illustrating a width of a differential signal transmission line, a thickness of an insulating layer, and a distance between the differential signal transmission line and a ground part for an impedance matching.

Referring to FIG. 4, the first wiring 210 and the second wiring 220 may each have a width w. In addition, the first wiring 210 and the second wiring 220 may be each disposed on a first surface and a second surface of the insulating layer 100, to have a spaced distance as much as a thickness d of the insulating layer 100.

In addition, the first wiring 210 may be disposed to be each spaced apart from the first ground layer 310 and the second ground layer 320 by s.

Here, w, d, and s may determine impedance of the differential signal transmission line 200. Specifically, as the widths w of the first wiring 210 and the second wiring 220 are increased, a parasitic capacitance value between the first wiring 210 and the second wiring 220 is decreased, such that the impedance value may be decreased. In addition, as the thickness d of the insulating layer 100, which is the distance between the first wiring 210 and the second wiring 220 is decreased, the capacitance value is increased, such that the impedance value may be decreased.

In addition, as the distance s between the first and second wirings 210 and 220 and the ground layer 310, 320, 330, and 340 is decreased, the capacitance value is increased, such that the impedance value may be decreased.

That is, since the wiring substrate according to an exemplary embodiment of the present disclosure may adjust impedance of the differential signal transmission line by adjusting the w, d, or s, it may more easily perform the impedance matching.

Therefore, in the case in which target impedance of the differential signal transmission line and a height d of the insulating layer 100 are determined in advance, the widths w of the first wiring 210 and the second wiring 220 may be determined depending on the target impedance and the height d of the insulating layer 100.

In addition, in the case in which target impedance and the widths w of the first wiring 210 and the second wiring 220 are determined in advance, the distance s between the first and second wirings 210 and 220 and the ground layers 310, 320, 330, and 340 may be determined depending on the w, d, and the target impedance.

According to an exemplary embodiment, the distance s between the first and second wirings 210 and 220 and the ground layers 310, 320, 330, and 340 may be less than the widths w of the first and second wirings 210 and 220.

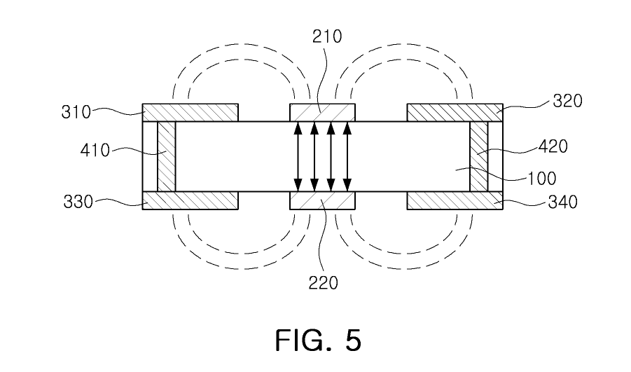

FIG. 5 is a view illustrating a shape of an electric field generated by the wiring substrate according to an exemplary embodiment of the present disclosure.

Referring to FIG. 5, the first wiring 210 and the second wiring 220 may be disposed to be vertically symmetrical to each other on the basis of the insulating layer 100 and when the differential signal flow in the first wiring 210 and the second wiring 220, an electromagnetic field may be formed through the insulating layer 100.

In addition, the electromagnetic field may be formed between the first wiring 210, and the first ground layer 310 and the second ground layer 320 disposed on the same plane as the first wiring 210, and the electromagnetic field may be formed between the second wiring 220, and the third ground layer 330 and the fourth ground layer 340 disposed on the same plane as the second wiring 220.

A coupling may be formed between the differential signals (a positive polarity signal and a negative polarity signal) flowing through the first wiring 210 and the second wiring 220 by the electromagnetic field formed as described above.

In addition, in the case in which reference levels of the ground layers 310 and 320 connected to the first wiring 210 and the ground layers 330 and 340 connected to the second wiring are different from each other, since amplitude between the positive polarity signal flowing through the first wiring 210 and the negative polarity signal flowing through the second wiring 220 is changed, the coupling between the two signal may not be properly implemented.

In this case, the first via 410 connects the firs ground layer 310 and the third ground layer 330 and the second via 420 connects the second ground layer 320 and the fourth ground layer 340, such that the ground layers 310 and 320 connected to the first wiring 210 and the ground layers 330 and 340 connected to the second wiring 220 may have the same reference level.

As set forth above, according to exemplary embodiments of the present disclosure, the distance between wirings transmitting differential signals maybe decreased by disposing the first and second wirings transmitting the differential signals to face each other on the basis of the insulating layer and impedance of the differential signal transmission lines may be easily adjusted by disposing the ground layers to be spaced apart from both sides of the wirings by a predetermined distance.

While exemplary embodiments have been shown and described above, it will be apparent to those skilled in the art that modifications and variations could be made without departing from the scope of the present invention as defined by the appended claims.

What is claimed is:

1. A wiring substrate comprising:
an insulating layer;
a differential signal transmission line configured to include a first wiring provided on a first surface of the insulating layer and a second wiring provided on a second surface of the insulating layer, the first wiring and the second wiring transmitting differential signals; and
a ground part configured to include a first ground layer and a second ground layer disposed to be spaced apart from the first wiring by the predetermined distance on the first surface of the insulating layer, and a third ground layer and a fourth ground layer disposed to be spaced apart from the second wiring by the predetermined distance on the second surface of the insulating layer.

2. The wiring substrate of claim 1, wherein the first wiring and the second wiring are disposed to be vertically symmetrical to each other on the basis of the insulating layer.

3. The wiring substrate of claim 1, wherein the first ground layer and the third ground layer are disposed to be vertically symmetrical to each other on the basis of the insulating layer, and
the second ground layer and the fourth ground layer are disposed to be vertically symmetrical to each other on the basis of the insulating layer.

4. The wiring substrate of claim 3, further comprising:
a first via configured to connect the first ground layer and the third ground layer; and
a second via configured to connect the second ground layer and the fourth ground layer.

5. The wiring substrate of claim 1, wherein a distance between the differential signal transmission line and the ground part is less than a width of the first wiring or the second wiring.

6. The wiring substrate of claim 1, wherein widths of the first wiring and the second wiring are determined depending on target impedance of the differential signal transmission line and a height of the insulating layer.

7. The wiring substrate of claim 1, wherein the ground part is disposed to be spaced apart from the first wiring or the second wiring by a first distance, and
the first distance is determined depending on target impedance of the differential signal transmission line, a height of the insulating layer, and widths of the first wiring and the second wiring.

8. A wiring substrate comprising:
an insulating layer;
a differential signal transmission line configured to include a first wiring provided on an upper surface of the insulating layer and a second wiring provided on a lower surface of the insulating layer; and
a ground part configured to include a first ground layer and a second ground layer disposed to be spaced apart from the first wiring by the predetermined distance on the upper surface of the insulating layer and a third ground layer and a fourth ground layer disposed to be spaced apart from the second wiring by the predetermined distance on the lower surface of the insulating layer,
wherein the first wiring and the second wiring transmit differential signals and are disposed to be vertically symmetrical to each other on the basis of the insulating layer,
the first ground layer and the third ground layer are disposed to be vertically symmetrical to each other on the basis of the insulating layer, and
the second ground layer and the fourth ground layer are disposed to be vertically symmetrical to each other on the basis of the insulating layer.

9. The wiring substrate of claim 8, further comprising:
a first via configured to connect the first ground layer and the third ground layer; and
a second via configured to connect the second ground layer and the fourth ground layer.

10. The wiring substrate of claim 8, wherein a distance between the differential signal transmission line and the ground part is less than a width of the first wiring or the second wiring.

11. The wiring substrate of claim 8, wherein widths of the first wiring and the second wiring are determined depending on target impedance of the differential signal transmission line and a height of the insulating layer.

12. The wiring substrate of claim 8, wherein the ground part is disposed to be spaced apart from the first wiring or the second wiring by a first distance, and
the first distance is determined depending on target impedance of the differential signal transmission line, a height of the insulating layer, and widths of the first wiring and the second wiring.
